(19) United States
(12) Patent Application Publication
(10) Pub. No.: US 2026/0206254 A1
(43) Pub. Date: Jul. 16, 2026

(54) SEMICONDUCTOR DEVICE

(71) Applicant: Samsung Electronics Co., Ltd., Suwon-si (KR)

(72) Inventors: Da Won JEONG, Suwon-si (KR); Jae-Hyun YOO, Suwon-si (KR); Hiroki FUJII, Suwon-si (KR); Yong Hee PARK, Suwon-si (KR); Kun Sik SUNG, Suwon-si (KR)

(21) Appl. No.: 19/311,194

(22) Filed: Aug. 27, 2025

(30) Foreign Application Priority Data
Jan. 10, 2025 (KR) 10-2025-0003976

(51) Int. Cl. H10D 30/65; H10D 30/01

(52) U.S. Cl. CPC H10D 30/658; H10D 30/0289

(57) ABSTRACT

A semiconductor device includes a substrate, a well region disposed inside the substrate, a first trench recessed from an upper surface of the substrate toward a lower surface of the substrate, a first drift region disposed on a first side of the first trench in a horizontal direction inside the well region, a portion of the first drift region overlapping with a bottom surface of the first trench in a vertical direction, a second drift region disposed on a second side of the first trench opposite to the first side of the first trench in the horizontal direction inside the well region, the second drift region spaced apart from the first drift region in the horizontal direction, a portion of the second drift region overlapping with the bottom surface of the first trench in the vertical direction, a first gate stack contacting the first drift region inside the first trench, the first gate stack conformally disposed along a first sidewall and the bottom surface of the first trench, a second gate stack contacting the second drift region inside the first trench, the second gate stack conformally disposed along a second sidewall and the bottom surface of the first trench, and a source region disposed between the first gate stack and the second gate stack inside the well region, the source region spaced apart from each of the first and second drift regions.

### CROSS-REFERENCE TO RELATED APPLICATION

This application claims priority from Korean Patent Application No. 10-2025-0003976 filed on Jan. 10, 2025 in the Korean Intellectual Property Office, the contents of which in its entirety are herein incorporated by reference.

### BACKGROUND

### 1. Technical Field

The present disclosure relates to a semiconductor device.

### 2. Description of the Related Art

As the miniaturization of semiconductor devices progresses, low-voltage scaling is being pursued, but there are cases where there is an internal boosting circuit or where the power supply voltage itself is around 12 V, such as in vehicles. To accommodate such applications, both low-voltage transistors and high-voltage transistors are integrated within the same semiconductor device. For example, in automotive applications high-voltage transistors may require a high breakdown voltage to operate at high voltages. Accordingly, research is being conducted to ensure a high breakdown voltage while reducing the size of high-voltage transistors.

### SUMMARY

The present disclosure may provide a semiconductor device that enhances the reliability of the semiconductor device by improving integration density while maintaining the current characteristics. The aspects of the present disclosure are not limited to those mentioned above, and other aspects which are not mentioned may be clearly understood by those skilled in the art from the description below.

According to some embodiments of the present disclosure, a semiconductor device includes a substrate, a well region disposed inside the substrate, a first trench recessed from an upper surface of the substrate toward a lower surface of the substrate, a first drift region disposed at a first side of the first trench in a horizontal direction inside the well region, a portion of the first drift region overlapping with a bottom surface of the first trench in a vertical direction, a second drift region disposed at a second side of the first trench opposite to the first side of the first trench in the horizontal direction inside the well region, the second drift region spaced apart from the first drift region in the horizontal direction, a portion of the second drift region overlapping with the bottom surface of the first trench in the vertical direction, a first gate stack contacting the first drift region inside the first trench, the first gate stack conformally disposed along a first sidewall and the bottom surface of the first trench, a second gate stack contacting the second drift region inside the first trench, the second gate stack conformally disposed along a second sidewall and the bottom surface of the first trench, and a source region disposed between the first gate stack and the second gate stack inside the well region, the source region spaced apart from each of the first and second drift regions.

According to some embodiments of the present disclosure, a semiconductor device includes a substrate, a well region disposed inside the substrate, a first trench recessed from an upper surface of the substrate toward a lower surface of the substrate, a first drift region disposed at a first side of the first trench in a horizontal direction inside the well region, a portion of the first drift region overlapping with a bottom surface of the first trench in a vertical direction, a second drift region disposed at a second side of the first trench opposite to the first side of the first trench in the horizontal direction inside the well region, the second drift region spaced apart from the first drift region in the horizontal direction, a portion of the second drift region overlapping with the bottom surface of the first trench in the vertical direction, a first gate stack contacting the first drift region inside the first trench, a second gate stack contacting the second drift region inside the first trench, the second gate stack spaced apart from the first gate stack in the horizontal direction, a first gate spacer disposed on opposite sidewalls of the first gate stack in the horizontal direction, the first gate spacer comprising a first portion overlapping the first drift region in the vertical direction and a second portion overlapping the first trench in the vertical direction, and a second gate spacer disposed on opposite sidewalls of the second gate stack in the horizontal direction, the second gate spacer comprising a first portion overlapping with the second drift region in the vertical direction and a second portion overlapping with the first trench in the vertical direction, wherein an upper surface of the second portion of the first gate spacer is formed lower than an upper surface of the first portion of the first gate spacer, and wherein an upper surface of the second portion of the second gate spacer is formed lower than an upper surface of the first portion of the second gate spacer.

According to some embodiments of the present disclosure, a semiconductor device includes a substrate, a well region disposed inside the substrate, a first trench recessed from an upper surface of the substrate toward a lower surface of the substrate, a first drift region disposed at a first side of the first trench in a first horizontal direction inside the well region, a portion of the first drift region overlapping with a bottom surface of the first trench in a vertical direction, a second drift region disposed at a second side of the first trench opposite to the first side of the first trench in the first horizontal direction inside the well region, the second drift region spaced apart from the first drift region in the first horizontal direction, a portion of the second drift region overlapping with the bottom surface of the first trench in the vertical direction, a first gate stack contacting the first drift region inside the first trench, the first gate stack conformally disposed along a first sidewall and the bottom surface of the first trench, a portion of the first gate stack contacting an upper surface of the first drift region, a second gate stack contacting the second drift region inside the first trench, the second gate stack conformally disposed along a second sidewall and the bottom surface of the first trench, a portion of the second gate stack contacting an upper surface of the second drift region, the second gate stack spaced apart from the first gate stack in the first horizontal direction on the bottom surface of the first trench, a source region disposed between the first gate stack and the second gate stack inside the well region, the source region spaced apart from each of the first and second drift regions, a first drain region disposed on one side of the first gate stack inside the first drift region, a second drain region disposed on one side of the second gate stack inside the second drift region, a first gate spacer disposed on opposite sidewalls of the first gate stack in the first horizontal direction, the first gate spacer comprising a first portion overlapping with the first drift region in the vertical direction and a second portion overlapping with the first trench in the vertical direction, and a second gate spacer disposed on opposite sidewalls of the second gate stack in the first horizontal direction, the second gate spacer comprising a first portion overlapping with the second drift region in the vertical direction and a second portion overlapping with the first trench in the vertical direction, wherein an upper surface of the second portion of the first gate spacer is formed lower than an upper surface of the first portion of the first gate spacer, and wherein an upper surface of the second portion of the second gate spacer is formed lower than an upper surface of the first portion of the second gate spacer.

### BRIEF DESCRIPTION OF THE DRAWINGS

The above and other aspects and features of the present disclosure will become more apparent by following detail description of exemplary embodiments thereof with reference to the attached (or accompanying) drawings, in which:

FIG. 1 is a diagram for explaining a semiconductor device according to some embodiments of the present disclosure;

FIGS. 2 to 8 are intermediate-stage diagrams for explaining a method for fabricating a semiconductor device according to some embodiments of the present disclosure;

FIG. 9 is a diagram for explaining a semiconductor device according to some other embodiments of the present disclosure;

FIG. 10 is a diagram for explaining a semiconductor device according to some other embodiments of the present disclosure;

FIG. 11 is a diagram for explaining a semiconductor device according to some other embodiments of the present disclosure;

FIG. 12 is a diagram for explaining a semiconductor device according to embodiments of the present disclosure;

FIG. 13 is a diagram for explaining a semiconductor device according to embodiments of the present disclosure;

FIG. 14 is a diagram for explaining a semiconductor device according to further embodiments of the present disclosure;

FIG. 15 is a diagram for explaining a semiconductor device according to further embodiments of the present disclosure; and

FIG. 16 is a diagram for explaining a semiconductor device according to further embodiments of the present disclosure.

### DETAILED DESCRIPTION OF THE EMBODIMENTS

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

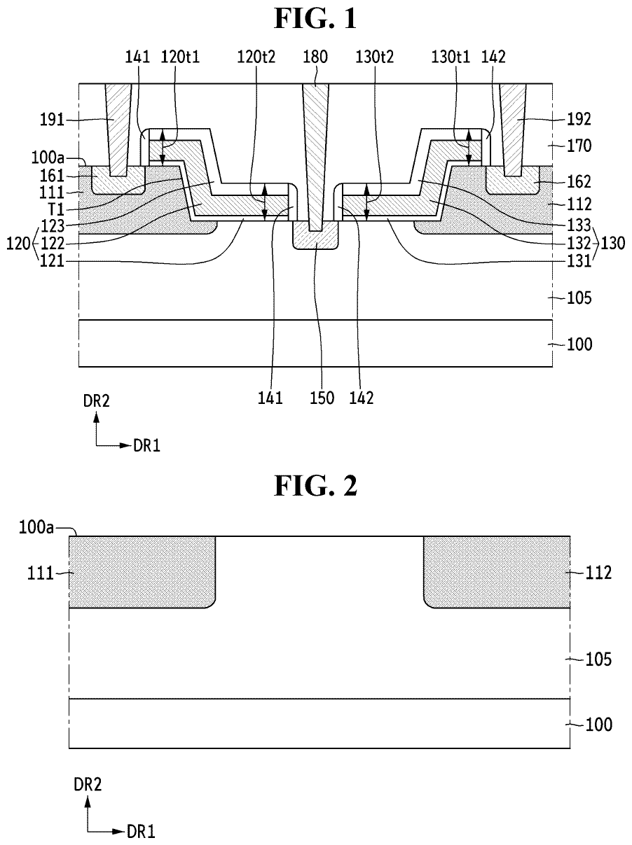

Hereinafter, a semiconductor device according to some embodiments of the present disclosure will be described with reference to FIG. 1.

FIG. 1 is a diagram for explaining a semiconductor device according to some embodiments of the present disclosure.

Referring to FIG. 1, the semiconductor device according to some embodiments of the present disclosure may include a substrate 100, a well region 105, first and second drift regions 111 and 112, a first trench T1, first and second gate structures 120 and 130, first and second gate spacers 141 and 142, a source region 150, first and second drain regions 161 and 162, an interlayer insulating layer 170, a source contact 180, first and second drain contacts 191 and 192. For example, the semiconductor device shown in FIG. 1 may be a high-voltage NMOS transistor.

The substrate 100 may be, for example, a silicon substrate, a gallium arsenide substrate, a silicon germanium substrate, a ceramic substrate, a quartz substrate, a glass substrate for display applications, or an SOI (Semiconductor On Insulator) substrate, but the technical concept of the present disclosure is not limited thereto. Hereinafter, a horizontal direction DR1 may be defined as a direction parallel to the upper surface 100a of the substrate 100. A vertical direction DR2 may be defined as a direction perpendicular to the horizontal direction DR1. For example, the vertical direction DR2 may be defined as a direction perpendicular to the upper surface 100a of the substrate 100.

The well region 105 may be disposed inside the substrate 100. For example, the well region 105 may be provided with the substrate 100. For example, the well region 105 may be a region doped with p-type impurities. The well region 105 may be formed by doping a portion of the substrate 100 with a p-type impurity. For example, in the cross-sectional view shown in FIG. 1, the well region 105 is shown to be disposed on the substrate 100, but since the well region 105 is formed by doping an impurity (charge carrier dopants) into a portion of the substrate 100, the well region 105 may be defined as being disposed inside the substrate 100. For example, the well region 105 may be provided within the substrate 100,

The first trench T1 may be formed to be recessed from the upper surface 100a of the substrate 100 toward the inside of the well region 105. For example, the first trench (or recess) T1 may extend from the upper surface 100a of the substrate 100 toward the lower surface of the substrate 100. For example, the first trench T1 may be formed inside the well region 105. For example, the first trench T1 may be formed within the well region 105. For example, the width of the first trench T1 in the horizontal direction DR1 may decrease gradually as it gets closer to the bottom surface of the first trench T1. For example, the sidewalls of the first trench T1 may have a slope profile.

A first drift region 111 may be disposed inside the well region 105. The first drift region 111 may be disposed on the first side of the first trench T1 in the horizontal direction DR1. For example, the first drift region 111 may form the first sidewall of the first trench T1. For example, the first drift region 111 may be in contact with the first sidewall of the first trench T1. For example, the first sidewall of the first trench T1 may be defined by the first drift region 111. For example, at least a portion of the first drift region 111 may be disposed beneath the bottom surface of the first trench T1. For example, at least a portion of the first drift region 111 may overlap with the bottom surface of the first trench T1 in the vertical direction DR2.

A second drift region 112 may be disposed inside the well region 105. The second drift region 112 may be disposed on the second side of the first trench T1 in the horizontal direction DR1, which is opposite to the first side of the first trench T1 in the horizontal direction DR1. For example, the second drift region 112 may form the second sidewall of the first trench T1. For example, the second sidewall of the first trench T1 may be defined by the second drift region 112. For example, at least a portion of the second drift region 112 may be disposed beneath the bottom surface of the first trench T1. For example, at least a portion of the second drift region 112 may overlap with the bottom surface of the first trench T1 in the vertical direction DR2. For example, beneath the bottom surface of the first trench T1, the second drift region 112 may be spaced apart from the first drift region 111 in the horizontal direction DR1.

For example, each of the first and second drift regions 111 and 112 may be a region doped with impurities having a conductivity type different from impurities doped in the well region 105. For example, each of the first and second drift regions 111 and 112 may be an n-type impurity-doped region. In the cross-sectional view shown in FIG. 1, each of the first and second drift regions 111 and 112 is depicted as being disposed on the well region 105, but since each of the first and second drift regions 111 and 112 is a region formed by doping impurities into a portion of the well region 105, each of the first and second drift regions 111 and 112 may be defined as being disposed inside the well region 105. For example, n-type impurity-doped region may be a region where the dominant impurities in the semiconductor region is (or are) n-type impurity.

In semiconductor technology, if a semiconductor contains both p-type and n-type impurities, the conductivity-type of the semiconductor will be determined by which type of impurity is in greater concentration. Therefore, if a semiconductor has both p-type and n-type impurities, the net conductivity type will be determined by the dominant impurity concentration. As used herein, a semiconductor region of a “first conductivity-type” denotes that the dominant impurities in the semiconductor region is (or are) a first conductivity-type impurity. As used herein, a “concentration of the first conductivity-type” in the semiconductor region (or a “doping concentration”) refers the net concentration of the impurities in the semiconductor region (i.e., (the amount of first conductivity-type impurities minus the amount of second conductivity-type impurities)/the volume of the semiconductor region).

For example, the uppermost surface of each of the first and second drift regions 111 and 112 may be coplanar with the upper surface 100a of the substrate 100. For example, the bottom surface of each of the first and second drift regions 111 and 112 may be formed lower than the bottom surface of the first trench T1.

The first gate structure 120 may be disposed inside the first trench T1. The first gate structure 120 may be a first gate stack. At least a portion of the first gate structure 120 may be disposed on the upper surface of the first drift region 111. For example, the first gate structure 120 may be in contact with both the well region 105 and the first drift region 111, which are disposed beneath the bottom surface of the first trench T1. The first gate structure 120 may be in contact with the first drift region 111 and the first sidewall of the first trench T1. The first gate structure 120 may be in contact with the upper surface of the first drift region 111 adjacent to the first sidewall of the first trench T1. For example, at least a portion of the first gate structure 120 may be in contact with the upper surface of the first drift region 111.

For example, the first gate structure 120 may be conformally disposed along the first sidewall and bottom surface of the first trench T1. Additionally, the first gate structure 120 may be conformally disposed on the upper surface of the first drift region 111 adjacent to the first sidewall of the first trench T1. Here, the meaning of being conformally disposed may refer to having a uniform thickness relative to the surface. For example, the thickness 120t1 in the vertical direction DR2 of the first gate structure 120 disposed on the upper surface of the first drift region 111 may be the same as the thickness 120t2 in the vertical direction DR2 of the first gate structure 120 disposed on the bottom surface of the first trench T1. For example, the upper surface of the first gate structure 120 disposed on the bottom surface of the first trench T1 may be formed lower than the upper surface of the first drift region 111. However, the present invention is not limited thereto.

The second gate structure 130 may be disposed inside the first trench T1. The second gate structure 130 may be a second gate stack. At least a portion of the second gate structure 130 may be disposed on the upper surface of the second drift region 112. For example, on the bottom surface of the first trench T1, the second gate structure 130 may be spaced apart from the first gate structure 120 in the horizontal direction DR1. For example, the second gate structure 130 may be in contact with both the well region 105 and the second drift region 112, which are disposed beneath the bottom surface of the first trench T1. The second gate structure 130 may be in contact with the second drift region 112 and the second sidewall of the first trench T1. For example, the second gate structure 130 may be in contact with the second drift region 112 and the second sidewall of the first trench T1. The second gate structure 130 may be in contact with the upper surface of the second drift region 112 adjacent to the second sidewall of the first trench T1. For example, at least a portion of the second gate structure 130 may be in contact with the upper surface of the second drift region 112.

For example, the second gate structure 130 may be disposed conformally along the second sidewall and bottom surface of the first trench T1. Additionally, the second gate structure 130 may be conformally disposed on the upper surface of the second drift region 112 adjacent to the second sidewall of the first trench T1. For example, the thickness 130t1 in the vertical direction DR2 of the second gate structure 130 disposed on the upper surface of the second drift region 112 may be the same as the thickness 130t2 in the vertical direction DR2 of the second gate structure 130 disposed on the bottom surface of the first trench T1. For example, the thickness 130t1 in the vertical direction DR2 of the second gate structure 130 disposed on the upper surface of the second drift region 112 may be the same as the thickness 120t1 in the vertical direction DR2 of the first gate structure 120 disposed on the upper surface of the first drift region 111. For example, the upper surface of the second gate structure 130 disposed on the bottom surface of the first trench T1 may be formed lower than the upper surface of the second drift region 112. However, the present disclosure is not limited thereto.

For example, the first gate structure (or gate stack) 120 may include a first gate insulating layer 121, a first gate electrode 122, and a first capping pattern 123. Additionally, the second gate structure 130 may include a second gate insulating layer 131, a second gate electrode 132, and a second capping pattern 133. For example, the first gate insulating layer 121 may be in contact with each of the well region 105 and the first drift region 111. The second gate insulating layer 131 may be in contact with each of the well region 105 and the second drift region 112. For example, each of the first and second gate insulating layers 121 and 131 may be formed conformally.

For example, each of the first and second gate insulating layers 121 and 131 may include silicon oxide, silicon oxynitride, silicon nitride, or a high-k dielectric material having a higher dielectric constant than silicon oxide. The high-k dielectric material may include, for example, one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate and combinations thereof, but is not limited to these.

The first gate electrode 122 may be in contact with the upper surface of the first gate insulating layer 121. The second gate electrode 132 may be in contact with the upper surface of the second gate insulating layer 131. For example, each of the first and second gate electrodes 122 and 132 may be formed conformally. For example, each of the first and second gate electrodes 122 and 132 may contain one or more of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first and second gate electrodes 122 and 132 may include polysilicon, conductive metal oxides, conductive metal oxynitrides, etc. and may also include oxidized forms of the above-mentioned materials.

The first capping pattern 123 may be in contact with the upper surface of the first gate electrode 122. The second capping pattern 133 may be in contact with the upper surface of the second gate electrode 132. For example, each of the first and second capping patterns 123 and 133 may be conformally formed. For example, each of the first and second capping patterns 123 and 133 may include at least one of silicon nitride (SiN), silicon oxynitride (SiON), silicon oxide (SiO2), silicon carbonitride (SiCN), silicon oxycarbonitride (SiOCN), and combinations thereof.

For example, both sidewalls in the horizontal direction DR1 of each of the first gate insulating layer 121, first gate electrode 122, and first capping pattern 123 may be in alignment. For example, both sidewalls in the horizontal direction DR1 of each of the first gate insulating layer 121, first gate electrode 122, and first capping pattern 123 may have a continuous slope profile. Additionally, both sidewalls in the horizontal direction DR1 of each of the second gate insulating layer 131, the second gate electrode 132, and the second capping pattern 133 may be in alignment. For example, both sidewalls in the horizontal direction DR1 of each of the second gate insulating layer 131, the second gate electrode 132, and the second capping pattern 133 may have a continuous slope profile.

A first gate spacer 141 may be disposed on both sidewalls of the first gate structure 120 in the horizontal direction DR1. For example, the first gate spacer 141 may be in contact with both sidewalls in the horizontal direction DR1 of each of the first gate insulating layer 121, the first gate electrode 122, and the first capping pattern 123. For example, the thickness of the first gate spacer 141 in the vertical direction DR2 may be the same as the thickness of the first gate structure 120 in the vertical direction DR2. For example, the first gate spacer 141 may include a first portion overlapping with the first drift region 111 in the vertical direction DR2 and a second portion overlapping with the first trench T1 in the vertical direction DR2.

For example, the first portion of the first gate spacer 141 may be in contact with the upper surface of the first drift region 111. The second portion of the first gate spacer 141 may be in contact with the upper surface of the well region 105. For example, the upper surface (or end) of the second portion of the first gate spacer 141 may be formed lower than the upper surface (or end) of the first portion of the first gate spacer 141. For example, the upper surface of the second portion of the first gate spacer 141 may be formed lower than the upper surface of the first drift region 111. However, the present invention is not limited thereto.

The second gate spacer 142 may be disposed on both sidewalls of the second gate structure 130 in the horizontal direction DR1. For example, the second gate spacer 142 may be in contact with both sidewalls in the horizontal direction DR1 of each of the second gate insulating layer 131, the second gate electrode 132, and the second capping pattern 133. For example, the thickness of the second gate spacer 142 in the vertical direction DR2 may be the same as the thickness of the second gate structure 130 in the vertical direction DR2. For example, the second gate spacer 142 may include a first portion overlapping with the second drift region 112 in the vertical direction DR2 and a second portion overlapping with the first trench T1 in the vertical direction DR2.

For example, the first portion of the second gate spacer 142 may be in contact with the upper surface of the second drift region 112. The second portion of the second gate spacer 142 may be in contact with the upper surface of the well region 105. For example, the upper surface of the second portion (or end) of the second gate spacer 142 may be formed lower than the upper surface (or end) of the first portion of the second gate spacer 142. For example, the upper surface of the second portion of the second gate spacer 142 may be formed lower than the upper surface of the second drift region 112. However, the present disclosure is not limited thereto. For example, the second portion of the second gate spacer 142 may be spaced apart from the second portion of the first gate spacer 141 in the horizontal direction DR1.

For example, each of the first and second gate spacers 141 and 142 may include at least one of silicon nitride (SiN), silicon oxynitride (SiON), silicon oxide (SiO2), silicon oxycarbonitride (SiOCN), silicon boronitride (SiBN), silicon oxyboronitride (SiOBN), silicon oxycarbide (SiOC), and combinations thereof.

The source region 150 may be disposed between the first gate structure 120 and the second gate structure 130 inside the well region 105. For example, the second gate structure 130 may be provided with the substrate 110. The source region 150 may be disposed between the first gate structure 120 and the second gate structure 130 beneath the bottom surface of the first trench T1. For example, the source region 150 may be spaced apart from each of the first and second drift regions 111 and 112 in the horizontal direction DR1. For example, the source region 150 may be spaced apart from the first drift region 111 in the horizontal direction DR1. Additionally, the second drift region 112 may be spaced apart from the source region 150 in the horizontal direction DR1. For example, the source region 150 may be an n-type impurity-doped region. For example, the concentration of n-type impurities doped in the source region 150 may be greater than the concentration of n-type impurities doped in the first and second drift regions 111 and 112.

The first drain region 161 may be disposed inside the first drift region 111. The first drain region 161 may be provided with the substrate 110. The first drain region 161 may be disposed on one side of the first gate structure 120. For example, the first gate structure 120 disposed on the first sidewall of the first trench T1 may be spaced apart from the first drain region 161 in the horizontal direction DR1. For example, at least a portion of the first drain region 161 may overlap with the first gate spacer 141 in the vertical direction DR2. The second drain region 162 may be disposed inside the second drift region 112. The second drain region 162 may be disposed on one side of the second gate structure 130. For example, the second drain region 162 may be spaced apart in the horizontal direction DR1 from the second gate structure 130, which is disposed on the second sidewall of the first trench T1. For example, at least a portion of the second drain region 162 may overlap with the second gate spacer 142 in the vertical direction DR2.

For example, the upper surface of the first drain region 161 may be coplanar with the upper surface of the first drift region 111. The upper surface of the second drain region 162 may be coplanar with the upper surface of the second drift region 112. For example, the upper surface of each of the first and second drain regions 161 and 162 may be formed higher than the upper surface of the source region 150. For example, each of the first and second drain regions 161 and 162 may be an n-type impurity-doped region. For example, the concentration of the n-type impurities doped in each of the first and second drain regions 161 and 162 may be greater than the concentration of the n-type impurities doped in the first and second drift regions 111 and 112.

The interlayer insulating layer 170 may be disposed on the upper surface 100a of the substrate 100. The interlayer insulating layer 170 may cover the upper surfaces of the first and second drift regions 111 and 112, the first and second drain regions 161 and 162, the source region 150, and the first and second gate structures 120 and 130, respectively. Additionally, the interlayer insulating layer 170 may surround the sidewalls of the first and second gate spacers 141 and 142, respectively. For example, at least a portion of the interlayer insulating layer 170 may be disposed between the first gate structure 120 and the second gate structure 130 inside the first trench T1.

For example, the interlayer insulating layer 170 may include at least one of silicon oxide, silicon nitride, silicon oxynitride, and low-k dielectric materials. Low-k dielectric materials include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, however, this is not intended to limit the scope of the invention.

The source contact 180 may be disposed on the upper surface of the source region 150. The source contact 180 may penetrate the interlayer insulating layer 170 in the vertical direction DR2 to electrically connect to the source region 150. The first drain contact 191 may be disposed on the upper surface of the first drain region 161. The first drain contact 191 may penetrate the interlayer insulating layer 170 in the vertical direction DR2 to electrically connect to the first drain region 161. The second drain contact 192 may be disposed on the upper surface of the second drain region 162. The second drain contact 192 may penetrate the interlayer insulating layer 170 in the vertical direction DR2 to electrically connect to the second drain region 162. The source contact 180, the first drain contact 191, and the second drain contact 192 may each include a conductive material.

Although not shown, a silicide layer containing a metal silicide material may be disposed at the interface between the source contact 180 and the source region 150. A silicide layer containing a metal silicide material may be disposed at the interface between the first drain contact 191 and the first drain region 161. A silicide layer containing a metal silicide material may be disposed at the interface between the second drain contact 192 and the second drain region 162.

In some embodiments of the present disclosure, the semiconductor device may dispose the source region 150 inside the first trench T1, so that the source region 150 may be spaced apart from the first drain region 161 in each of the horizontal direction DR1 and the vertical direction DR2. For example, the current between the source region 150 and the first drain region 161 may flow in each of the horizontal direction DR1 and the vertical direction DR2. Consequently, as compared to the conventional planar transistor in which the source and drain regions are spaced apart only in the horizontal direction, the semiconductor device according to some embodiments of the present disclosure may achieve the same breakdown voltage as the conventional planar transistor while reducing the size as compared to the conventional planar transistor.

Additionally, in the semiconductor device according to some embodiments of the present disclosure, at least a portion of the first drift region 111 may be formed beneath the bottom surface of the first trench T1. Beneath the bottom surface of the first trench T1, a channel region may be formed in the horizontal direction DR1 between the first drift region 111 and the source region 150. As a result, the semiconductor device according to some embodiments of the present disclosure may achieve the same breakdown voltage as the conventional planar transistor while reducing the length of the channel region as compared to the conventional planar transistor. Consequently, the semiconductor device according to some embodiments of the present disclosure may improve the reliability of the semiconductor device by enhancing the integration density while maintaining the current characteristics.

For example, though not shown in the drawings, the MOS transistor (or transistors) shown in FIG. 1 may have symmetry in the arrangement of the components in a plan view. The components of the MOS transistor may be arranged symmetrically with respect to an imaginary plane extending in the vertical direction DR2 and in an additional horizontal direction which is perpendicular to the horizontal direction DR1 and the vertical direction DR2.

The first trench T1 may have a symmetrical shape with respect to the imaginary plane. The imaginary plane may intersect the center of the first trench T1. The first drift region 111 and the second drift region 112 may be disposed symmetrically with respect to the imaginary plane. The first gate structure 120 and the second gate structure 130 may be disposed symmetrically with respect to the imaginary plane. The components of the first gate structure 120 and the second gate structure 130 may be disposed symmetrically with respect to the imaginary plane. The first and second gate spacers 141 and 142 may be disposed symmetrically with respect to the imaginary plane. The source region 150 may have a symmetrical shape with respect to the imaginary plane. The imaginary plane may intersect the center of the source region 150. The first and second drain regions 161 and 162 may be disposed symmetrically with respect to the imaginary plane.

In some embodiments, though not shown in the drawings, the components shown in FIG. 1 may constitute a single MOS transistor. For example, the first drift region 111 and the second drift region 112 may constitute a single continuous body surrounding the first trench T1 and the source region 150 in a plan view, the first gate structure 120 and the second gate structure 130 may constitute a single continuous body surrounding the first trench T1 and the source region 150 in a plan view, the first and second drain regions 161 and 162 may constitute a single continuous body surrounding the first trench T1 and the source region 150 in a plan view.

In some embodiments, though not shown in the drawings, a third drift region may be provided within the substrate 105 such that 150 is disposed within the third drift region. The third drift region may be a region doped with impurities having a conductivity type different from impurities doped in the well region 105. The third drift region may be a region doped with impurities having the conductivity type same as those of the first and second drift regions 111 and 112.

In some embodiments, the role of component 150 may be interchanged with that of components 161 and 162 during the operation of the MOS transistor. For example, components 161 and 162 may serve as source regions, while component 150 may function as a drain region.

Hereinafter, a method for fabricating a semiconductor device according to embodiments of the present disclosure will be described with reference to FIGS. 1 to 8.

FIGS. 2 to 8 are intermediate-stage drawings for explaining the method for fabricating a semiconductor device according to some embodiments of the present disclosure.

Referring to FIG. 2, a well region 105 may be formed in the substrate 100. For example, the well region 105 may be formed by doping p-type impurities inside the substrate 100. For example, the upper surface of the well region 105 may be coplanar with the upper surface 100a of the substrate 100.

Subsequently, first and second drift regions 111 and 112 may be formed inside the well region 105. For example, the second drift region 112 may be spaced apart from the first drift region 111 in the horizontal direction DR1. For example, each of the first and second drift regions 111 and 112 may be formed by doping with n-type impurities. For example, the upper surface of each of the first and second drift regions 111 and 112 may be coplanar with the upper surface of the well region 105.

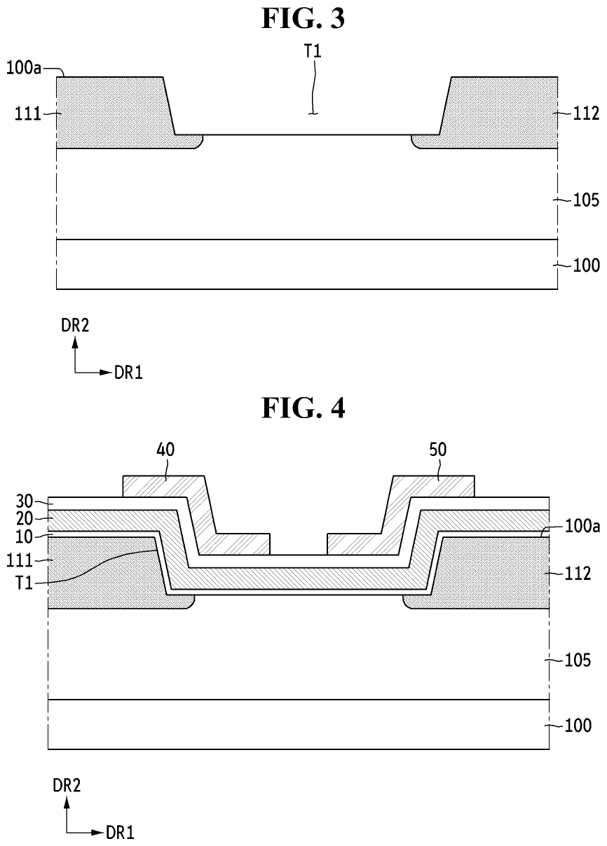

Referring to FIG. 3, a first trench T1 may be formed in the well region 105. For example, the first trench T1 may be formed to be recessed from the upper surface 100a of the substrate 100 toward the inside of the well region 105. For example, during the formation of the first trench T1, a portion of each of the first and second drift regions 111 and 112 may be etched. The first sidewall of the first trench T1 may be defined as the first drift region 111, and the second sidewall of the first trench T1 may be defined as the second drift region 112. For example, at least a portion of each of the first and second drift regions 111 and 112 may be disposed beneath the bottom surface of the first trench T1. For example, at least a portion of each of the first and second drift regions 111 and 112 may overlap with the bottom surface of the first trench T1 in the vertical direction DR2.

Referring to FIG. 4, a gate insulating material layer 10, a gate electrode material layer 20, and a capping material layer 30 may be sequentially formed on the surface of the first trench T1, the upper surface of the first drift region 111, and the upper surface of the second drift region 112. For example, the gate insulating material layer 10, the gate electrode material layer 20, and the capping material layer 30 may be formed conformally. For example, the gate insulating material layer 10 may include the same material as the first and second gate insulating layers 121 and 131 shown in FIG. 1. The gate electrode material layer 20 may include the same material as each of the first and second gate electrodes 122 and 132 shown in FIG. 1. The capping material layer 30 may include the same material as each of the first and second capping patterns 123 and 133 shown in FIG. 1.

Subsequently, first and second mask patterns 40 and 50 may be formed on the upper surface of the capping material layer 30. For example, each of the first and second mask patterns 40 and 50 may overlap with the bottom surface of the first trench T1 in the vertical direction DR2. For example, on the bottom surface of the first trench T1, the second mask pattern 50 may be spaced apart from the first mask pattern 40 in the horizontal direction DR1. For example, at least a portion of the first mask pattern 40 may overlap with the upper surface of the first drift region 111 in the vertical direction DR2. Additionally, at least a portion of the second mask pattern 50 may overlap with the upper surface of the second drift region 112 in the vertical direction DR2.

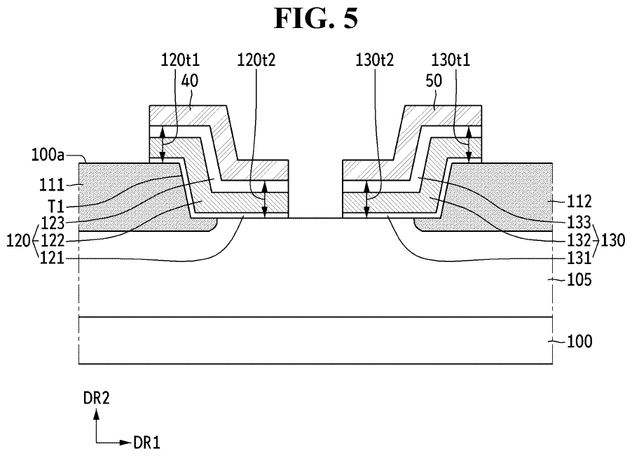

Referring to FIG. 5, using the first and second mask patterns 40 and 50 as masks, each of the gate insulating material layer 10 (see FIG. 4), the gate electrode material layer 20 (see FIG. 4), and the capping material layer 30 (see FIG. 4) may be etched. After this etching process is completed, the gate insulating material layer 10 (see FIG. 4), the gate electrode material layer 20 (see FIG. 4), and the capping material layer 30 (see FIG. 4) remaining beneath the first mask pattern 40 may be defined as the first gate insulating layer 121, the first gate electrode 122, and the first capping pattern 123, respectively. For example, a first gate structure 120 including the first gate insulating layer 121, the first gate electrode 122 and the first capping pattern 123 may be formed beneath the first mask pattern 40. At least a portion of the first gate structure 120 may be formed inside the first trench T1.

Additionally, after this etching process is completed, the gate insulating material layer 10 (see FIG. 4), the gate electrode material layer 20 (see FIG. 4), and the capping material layer 30 (see FIG. 4) remaining beneath the second mask pattern 50 may be defined as the second gate insulating layer 131, the second gate electrode 132, and the second capping pattern 133, respectively. For example, a second gate structure 130, which includes the second gate insulating layer 131, the second gate electrode 132, and the second capping pattern 133 may be formed beneath the second mask pattern 50. At least a portion of the second gate structure 130 may be formed inside the first trench T1. For example, on the bottom surface of the first trench T1, the second gate structure 130 may be spaced apart from the first gate structure 120 in the horizontal direction DR1.

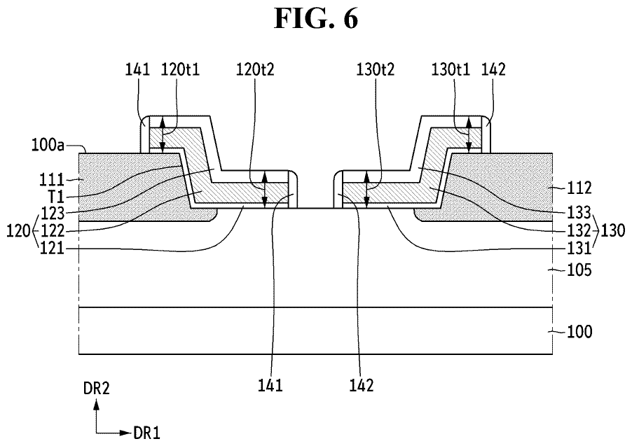

Referring to FIG. 6, the first and second mask patterns 40 and 50 (see FIG. 5) may each be removed. Subsequently, a first gate spacer 141 may be formed on both sidewalls of the first gate structure 120 in the horizontal direction DR1. In addition, a second gate spacer 142 may be formed on both sidewalls of the second gate structure 130 in the horizontal direction DR1.

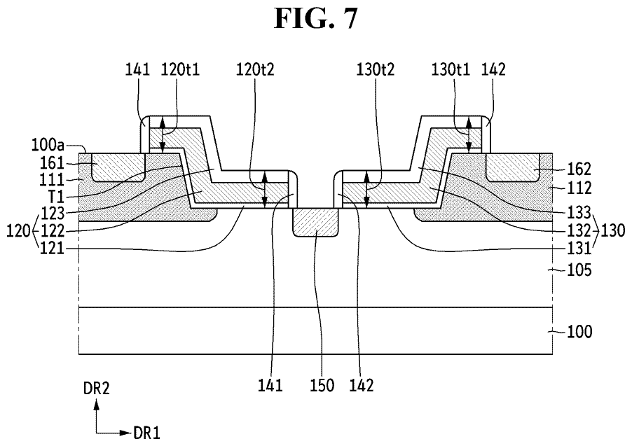

Referring to FIG. 7, a source region 150 may be formed between the first gate structure 120 and the second gate structure 130. The source region 150 may be formed inside the well region 105, which is exposed through the bottom surface of the first trench T1. Additionally, a first drain region 161 may be formed on one side of the first gate structure 120 inside the first drift region 111, and a second drain region 162 may be formed on one side of the second gate structure 130 inside the second drift region 112. For example, the source region 150 and the first and second drain regions 161 and 162 may each be an n-type impurity-doped region. For example, the concentration of n-type impurities doped in the source region 150 and the first and second drain regions 161 and 162 may be greater than the concentration of n-type impurities doped in the first and second drift regions 111 and 112.

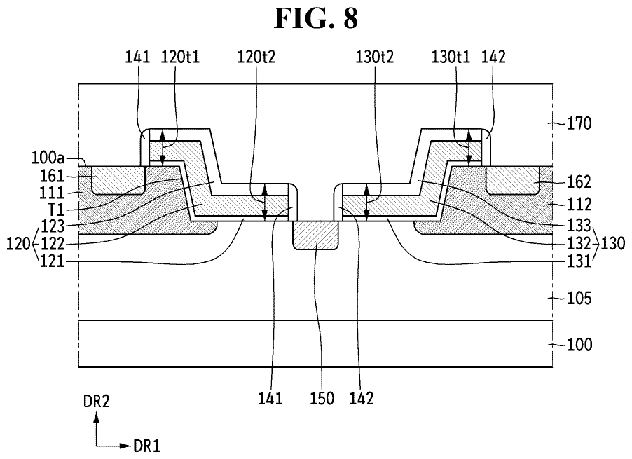

Referring to FIG. 8, an interlayer insulating layer 170 may be formed on the upper surface of each of the first and second drift regions 111 and 112, the first and second drain regions 161 and 162, the source region 150, and the first and second gate structures 120 and 130. The interlayer insulating layer 170 may surround the sidewalls of each of the first and second gate spacers 141 and 142.

Referring to FIG. 1, a source contact 180 that penetrates the interlayer insulating layer 170 in the vertical direction DR2 and is electrically connected to the source region 150 may be formed. Additionally, a first drain contact 191 that penetrates the interlayer insulating layer 170 in the vertical direction DR2 and is electrically connected to the first drain region 161 may be formed. Additionally, a second drain contact 192 that penetrates the interlayer insulating layer 170 in the vertical direction DR2 and is electrically connected to the second drain region 162 may be formed. The semiconductor device shown in FIG. 1 may be fabricated through these fabrication processes.

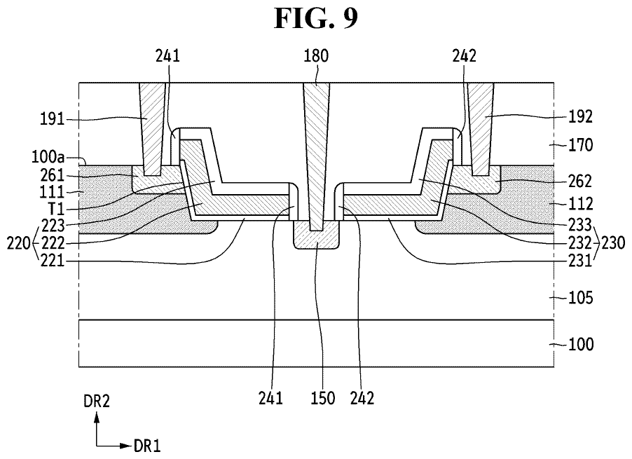

Hereinafter, a semiconductor device according to other embodiments of the present disclosure will be described with reference to FIG. 9. The description may focus on the differences from the semiconductor device shown in FIG. 1.

FIG. 9 is a diagram for explaining the semiconductor device according to some other embodiments of the present disclosure.

Referring to FIG. 9, in the semiconductor device according to other embodiments of the present disclosure, the first drain region 261 may be in contact with the first gate structure 220, and the second drain region 262 may be in contact with the second gate structure 230.

For example, the first gate structure 220 may include a first gate insulating layer 221, a first gate electrode 222, and a first capping pattern 223. For example, the first drain region 261 may be in contact with the first gate structure 220, which is disposed on the first sidewall of the first trench T1. For example, the first drain region 261 may be in contact with the first gate insulating layer 221, which is disposed on the first sidewall of the first trench T1. For example, the second gate structure 230 may include a second gate insulating layer 231, a second gate electrode 232, and a second capping pattern 233. The second drain region 262 may be in contact with the second gate structure 230, which is disposed on the second sidewall of the first trench T1. For example, the second drain region 262 may be in contact with the second gate insulating layer 231, which is disposed on the second sidewall of the first trench T1.

For example, the first gate spacer 241 may be disposed on both sidewalls of the first gate structure 220 in the horizontal direction DR1. The first gate spacer 241 may be in contact with the upper surface of the first drain region 261. The second gate spacer 242 may be disposed on both sidewalls of the second gate structure 230 in the horizontal direction DR1. The second gate spacer 242 may be in contact with the upper surface of the second drain region 262.

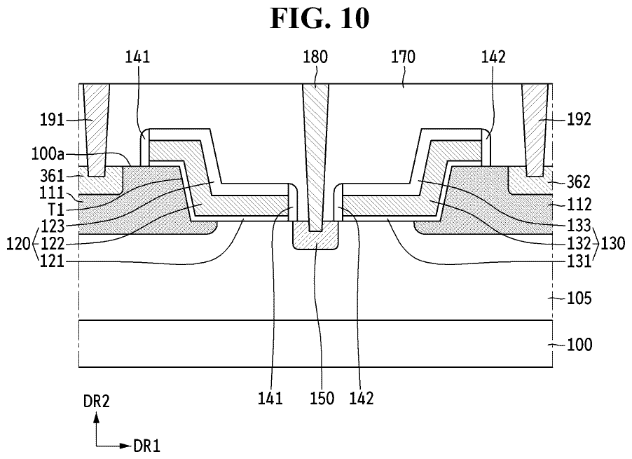

Hereinafter, the semiconductor device according to other embodiments of the present disclosure will be described with reference to FIG. 10. It will be explained mainly in terms of the differences from the semiconductor device shown in FIG. 1.

FIG. 10 is a diagram for explaining the semiconductor device according to some other embodiments of the present disclosure.

Referring to FIG. 10, in the semiconductor device according to other embodiments of the present disclosure, the first drain region 361 does not overlap with the first gate spacer 141 in the vertical direction DR2, and the second drain region 362 does not overlap with the second gate spacer 142 in the vertical direction DR2.

For example, the first gate spacer 141, which is in contact with the upper surface of the first drift region 111, may be spaced apart from the first drain region 361 in the horizontal direction DR1. The second drain region 362 may be spaced apart from the second gate spacer 142, which is in contact with the upper surface of the second drift region 112, in the horizontal direction DR1.

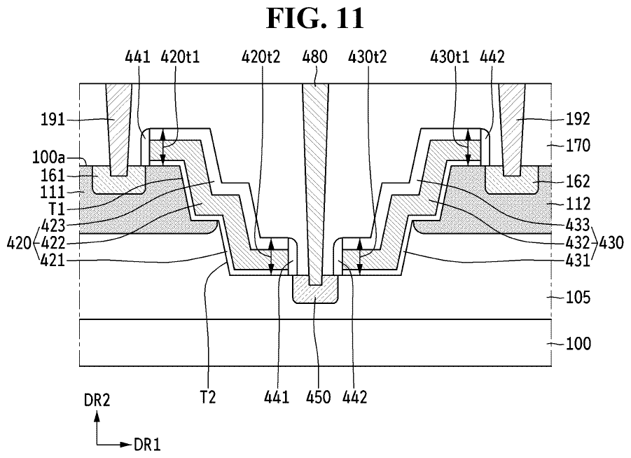

Hereinafter, a semiconductor device according to other embodiments of the present disclosure will be described with reference to FIG. 11. The differences from the semiconductor device shown in FIG. 1 will be explained.

FIG. 11 is a diagram for explaining the semiconductor device according to other embodiments of the present disclosure.

Referring to FIG. 11, in the semiconductor device according to other embodiments of the present disclosure, a second trench T2 may be formed beneath the first trench T1, and first and second gate structures 420, 430 may be arranged inside the second trench T2.

For example, the second trench T2 may be formed to be recessed from the bottom surface of the first trench T1 toward the inside of the well region 105. For example, the second trench (or recess) T2 may extend from the bottom surface of the first trench T1 toward the lower surface of the substrate 100. For example, the second trench T2 may be formed inside the well region 105. For example, the width of the second trench T2 in the horizontal direction DR1 may decrease continuously (or gradually) as it gets closer to the bottom surface of the second trench T2. For example, the sidewalls of the second trench T2 may have a slope profile. For example, the width of the second trench T2 in the horizontal direction DR1 may be smaller than the width of the first trench T1 in the horizontal direction DR1.

For example, the first gate structure 420 may be disposed inside both the first trench T1 and the second trench T2. At least a portion of the first gate structure 420 may be disposed on the upper surface of the first drift region 111. For example, the first gate structure 420 may be in contact with the first drift region 111, which is disposed beneath the bottom surface of the first trench T1. The first gate structure 420 may be in contact with the first drift region 111 that forms the first sidewall of the first trench T1. For example, the first gate structure 420 may be in contact with the well region 105, which is disposed beneath the bottom surface of the second trench T2. The first gate structure 420 may be in contact with the well region 105 that forms the first sidewall of the second trench 2. The first gate structure 420 may be in contact with the upper surface of the first drift region 111 adjacent to the first sidewall of the first trench T1.

For example, the first gate structure 420 may be conformally disposed along the first sidewall and bottom surface of the first trench T1 and the first sidewall and bottom surface of the second trench T2. Additionally, the first gate structure 420 may be conformally disposed on the upper surface of the first drift region 111 adjacent to the first sidewall of the first trench T1. For example, the thickness 420t1 in the vertical direction DR2 of the first gate structure 420 disposed on the upper surface of the first drift region 111 may be the same as the thickness 420t2 in the vertical direction DR2 of the first gate structure 420 disposed on the bottom surface of the second trench T2.

For example, the second gate structure 430 may be disposed inside both the first trench T1 and the second trench T2. At least a portion of the second gate structure 430 may be disposed on the upper surface of the second drift region 112. For example, on the bottom surface of the second trench T2, the second gate structure 430 may be spaced apart from the first gate structure 420 in the horizontal direction DR1. For example, the second gate structure 430 may be in contact with the second drift region 112 disposed beneath the bottom surface of the first trench T1. The second gate structure 430 may be in contact with the second drift region 112 and the second side wall of the first trench T1. For example, the second gate structure 430 may be in contact with the well region 105 disposed beneath the bottom surface of the second trench T2. The second gate structure 430 may be in contact with the well region 105, which is in contact with the second sidewall of the second trench 2. The second gate structure 430 may be in contact with the upper surface of the second drift region 112 adjacent to the second sidewall of the first trench T1.

For example, the second gate structure 430 may be conformally disposed along the second sidewall and bottom surface of the first trench T1 and the second sidewall and bottom surface of the second trench T2. Additionally, the second gate structure 430 may be conformally disposed on the upper surface of the second drift region 112 adjacent to the second sidewall of the first trench T1. For example, the thickness 430t1 in the vertical direction DR2 of the second gate structure 430 disposed on the upper surface of the second drift region 112 may be the same as the thickness 430t2 in the vertical direction DR2 of the second gate structure 430 disposed on the bottom surface of the second trench T2.

For example, the first gate structure 420 may include a first gate insulating layer 421, a first gate electrode 422, and a first capping pattern 423, which are sequentially stacked. Additionally, the second gate structure 430 may include a second gate insulating layer 431, a second gate electrode 432, and a second capping pattern 433, which are sequentially stacked.

For example, the first gate spacer 441 may be disposed on both sidewalls of the first gate structure 420 in the horizontal direction DR1. For example, the first gate spacer 441 may include a first portion that overlaps with the first drift region 111 in the vertical direction DR2 and a second portion that overlaps with the second trench T2 in the vertical direction DR2. For example, the upper surface (or end) of the second portion of the first gate spacer 441 may be formed lower than the upper surface (or end) of the first portion of the first gate spacer 441.

For example, the second gate spacer 442 may be disposed on both sidewalls of the second gate structure 430 in the horizontal direction DR1. For example, the second gate spacer 442 may include a first portion that overlaps with the second drift region 112 in the vertical direction DR2 and a second portion that overlaps with the second trench T2 in the vertical direction DR2. For example, the upper surface (or end) of the second portion of the second gate spacer 442 may be formed lower than the upper surface (or end) of the first portion of the second gate spacer 442.

For example, the bottom surface of the first drift region 111 and the bottom surface of the second drift region 112 may each be formed higher than the bottom surface of the second trench T2. Although FIG. 11 shows that each of the first and second drift regions 111 and 112 is spaced apart from the sidewalls of the second trench T2 in the horizontal direction DR1, the present invention is not limited thereto. In some other embodiments, the first drift region 111 may be in contact with the first gate structure 420 disposed on the first sidewall of the second trench T2, and the second drift region 112 may be in contact with the second gate structure 430 disposed on the second sidewall of the second trench T2.

For example, the source region 450 may be disposed between the first gate structure 420 and the second gate structure 430 inside the well region 105. The source region 450 may be disposed between the first gate structure 420 and the second gate structure 430 beneath the bottom surface of the second trench 2. For example, the source contact 480 may be disposed on the upper surface of the source region 450. The source contact 480 may penetrate the interlayer insulating layer 170 in the vertical direction DR2 to be electrically connected to the source region 450.

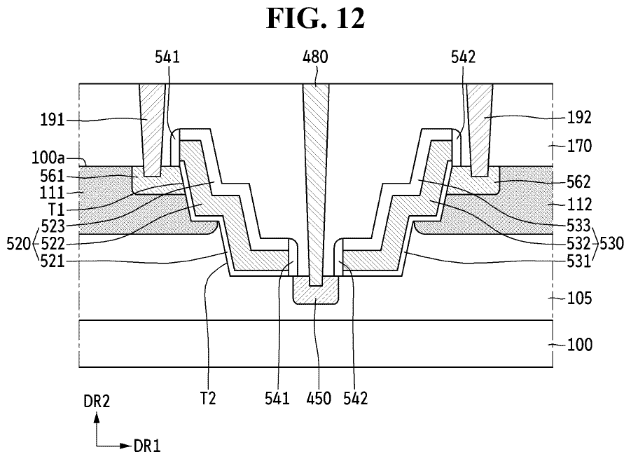

Hereinafter, a semiconductor device according to other embodiments of the present disclosure will be described with reference to FIG. 12. The differences from the semiconductor device shown in FIG. 11 are explained.

FIG. 12 is a diagram for explaining the semiconductor device according to other embodiments of the present disclosure.

Referring to FIG. 12, in the semiconductor device according to other embodiments of the present disclosure, a first drain region 561 may be in contact with the first gate structure 520, and a second drain region 562 may be in contact with the second gate structure 530.

For example, the first gate structure 520 may include a first gate insulating layer 521, a first gate electrode 522, and a first capping pattern 523. For example, the first drain region 561 may be in contact with the first gate structure 520 disposed on the first sidewall of the first trench T1. For example, the first drain region 561 may be in contact with the first gate insulating layer 521 disposed on the first sidewall of the first trench T1. For example, the second gate structure 530 may include a second gate insulating layer 531, a second gate electrode 532, and a second capping pattern 533. The second drain region 562 may be in contact with the second gate structure 530 disposed on the second sidewall of the first trench T1. For example, the second drain region 562 may be in contact with the second gate insulating layer 531 disposed on the second sidewall of the first trench T1.

For example, the first gate spacer 541 may be disposed on both sidewalls of the first gate structure 520 in the horizontal direction DR1. The first gate spacer 541 may be in contact with the upper surface of the first drain region 561. The second gate spacer 542 may be disposed on both sidewalls of the second gate structure 530 in the horizontal direction DR1. The second gate spacer 542 may be in contact with the upper surface of the second drain region 562.

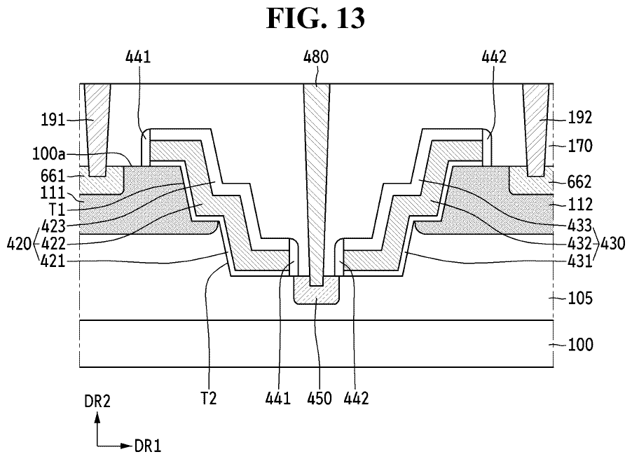

Hereinafter, a semiconductor device according to other embodiments of the present disclosure will be described with reference to FIG. 13. The description will focus on the differences from the semiconductor device shown in FIG. 11.

FIG. 13 is a diagram for explaining a semiconductor device according to other embodiments of the present disclosure.

Referring to FIG. 13, in the semiconductor device according to other embodiments of the present disclosure, the first drain region 661 does not overlap with the first gate spacer 441 in the vertical direction DR2, and the second drain region 662 does not overlap with the second gate spacer 442 in the vertical direction DR2.

For example, the first gate spacer 441, which is in contact with the upper surface of the first drift region 111 may be spaced apart from the first drain region 661 in the horizontal direction DR1. The second drain region 662 may be spaced apart from the second gate spacer 442, which is in contact with the upper surface of the second drift region 112, in the horizontal direction DR1.

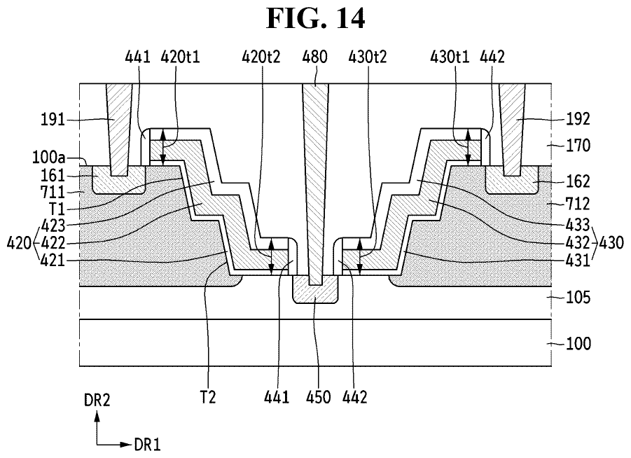

Hereinafter, a semiconductor device according to other embodiments of the present disclosure will be described with reference to FIG. 14. description will focus on the differences from the semiconductor device shown in FIG. 11.

FIG. 14 is a diagram for explaining a semiconductor device according to other embodiments of the present disclosure.

Referring to FIG. 14, in the semiconductor device according to other embodiments of the present disclosure, at least a portion of the first drift region 711 and at least a portion of the second drift region 712 may overlap with the bottom surface of the second trench T2 in the vertical direction DR2.

For example, the first drift region 711 may be disposed on the first side of both the first trench T1 and the second trench T2 in the horizontal direction DR1. For example, the first drift region 711 may form the first sidewall and bottom surface of the first trench T1. Additionally, the first drift region 711 may form the first sidewall of the second trench T2. For example, at least a portion of the first drift region 711 may be disposed beneath the bottom surface of the second trench T2.

For example, the second drift region 712 may be disposed on the second side of both the first trench T1 and the second trench T2 in the horizontal direction DR1. For example, the second drift region 712 may form the second sidewall and bottom surface of the first trench T1. Additionally, the second drift region 712 may form the second sidewall of the second trench T2. For example, at least a portion of the second drift region 712 may be disposed beneath the bottom surface of the second trench T2.

For example, beneath the bottom surface of the second trench T2, the second drift region 712 may be spaced apart from the first drift region 711 in the horizontal direction DR1. For example, the source region 450 may be disposed between the first drift region 711 and the second drift region 712 beneath the bottom surface of the second trench T2. For example, the bottom surface of each of the first and second drift regions 711, 712 may be disposed lower than the bottom surface of the second trench T2.

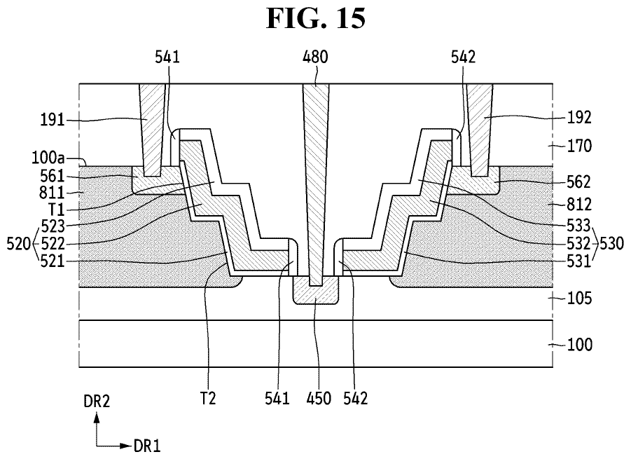

Hereinafter, a semiconductor device according to other embodiments of the present disclosure will be described with reference to FIG. 15. The description may focus on the differences from the semiconductor device shown in FIG. 12.

FIG. 15 is a diagram for explaining a semiconductor device according to other embodiments of the present disclosure.

Referring to FIG. 15, in the semiconductor device according to other embodiments of the present disclosure, at least a portion of the first drift region 811 and at least a portion of the second drift region 812 may overlap with the bottom surface of the second trench T2 in the vertical direction DR2.

For example, the first drift region 811 may be disposed on the first side of each of the first trench T1 and the second trench T2 in the horizontal direction DR1. For example, the first drift region 811 may form the first sidewall and bottom surface of the first trench T1. Additionally, the first drift region 811 may form the first sidewall of the second trench T2. For example, at least a portion of the first drift region 811 may be disposed beneath the bottom surface of the second trench T2.

For example, the second drift region 812 may be disposed on the second side of each of the first trench T1 and the second trench T2 in the horizontal direction DR1. For example, the second drift region 812 may form the second sidewall and bottom surface of the first trench T1. Additionally, the second drift region 812 may form the second sidewall of the second trench 2. For example, at least a portion of the second drift region 812 may be disposed beneath the bottom surface of the second trench T2.

For example, beneath the bottom surface of the second trench T2, the second drift region 812 may be spaced apart from the first drift region 811 in the horizontal direction DR1. For example, beneath the bottom surface of the second trench T2, the source region 450 may be disposed between the first drift region 811 and the second drift region 812. For example, the bottom surface of each of the first and second drift regions 811, 812 may be disposed lower than the bottom surface of the second trench T2.

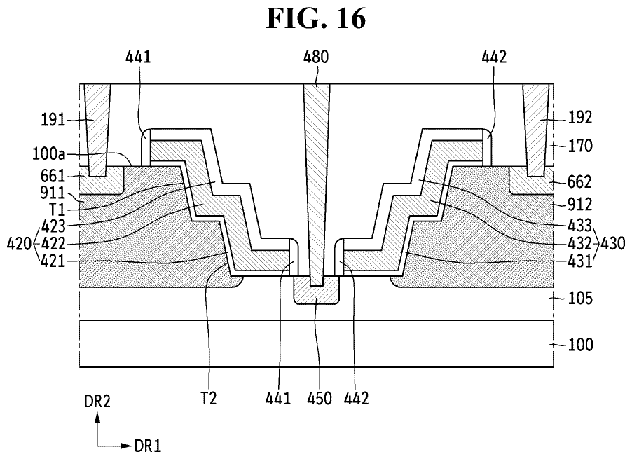

Hereinafter, a semiconductor device according to other embodiments of the present disclosure will be described with reference to FIG. 16. The differences from the semiconductor device shown in FIG. 13 are explained.

FIG. 16 is a diagram for explaining a semiconductor device according to other embodiments of the present disclosure.

Referring to FIG. 16, in the semiconductor device according to other embodiments of the present disclosure, at least a portion of the first drift region 911 and at least a portion of the second drift region 912 may overlap with the bottom surface of the second trench T2 in the vertical direction DR2.

For example, the first drift region 911 may be disposed on the first side of each of the first trench T1 and the second trench T2 in the horizontal direction DR1. For example, the first drift region 911 may form the first sidewall and bottom surface of the first trench T1. Additionally, the first drift region 911 may form the first sidewall of the second trench 2. For example, at least a portion of the first drift region 911 may be disposed beneath the bottom surface of the second trench T2.

For example, the second drift region 912 may be disposed on the second side of each of the first trench T1 and the second trench T2 in the horizontal direction DR1. For example, the second drift region 912 may form the second sidewall and bottom surface of the first trench T1. Additionally, the second drift region 912 may form the second sidewall of the second trench T2. For example, at least a portion of the second drift region 912 may be disposed beneath the bottom surface of the second trench T2.

For example, beneath the bottom surface of the second trench T2, the second drift region 912 may be spaced apart from the first drift region 911 in the horizontal direction DR1. For example, beneath the bottom surface of the second trench T2, the source region 450 may be disposed between the first drift region 911 and the second drift region 912. For example, the bottom surface of each of the first and second drift regions 911, 912 may be disposed lower than the bottom surface of the second trench T2.

While the embodiments of the present disclosure have been described above with reference to the accompanying drawings, the present invention is not limited to these embodiments and may be implemented in various other forms. Those of ordinary skill in the art to which the present disclosure pertains will understand that the invention may be practiced in other specific forms without departing from the technical spirit or essential characteristics of the present disclosure. Accordingly, the above-described embodiments should be understood as illustrative in all respects and not restrictive.

What is claimed is:

1. A semiconductor device comprising:
a substrate;
a well region disposed inside the substrate;
a first trench recessed from an upper surface of the substrate toward a lower surface of the substrate;
a first drift region disposed at a first side of the first trench in a horizontal direction inside the well region, a portion of the first drift region overlapping with a bottom surface of the first trench in a vertical direction;
a second drift region disposed at a second side of the first trench opposite to the first side of the first trench in the horizontal direction inside the well region, the second drift region spaced apart from the first drift region in the horizontal direction, a portion of the second drift region overlapping with the bottom surface of the first trench in the vertical direction;
a first gate stack contacting the first drift region inside the first trench, the first gate stack conformally disposed along a first sidewall and the bottom surface of the first trench;
a second gate stack contacting the second drift region inside the first trench, the second gate stack conformally disposed along a second sidewall and the bottom surface of the first trench; and
a source region disposed between the first gate stack and the second gate stack inside the well region, the source region spaced apart from each of the first and second drift regions.

2. The semiconductor device of claim 1, further comprising:
a first drain region disposed on one side of the first gate stack inside the first drift region; and
a second drain region disposed on one side of the second gate stack inside the second drift region.

3. The semiconductor device of claim 2, wherein the first gate stack disposed on the first sidewall of the first trench is spaced apart from the first drain region in the horizontal direction, and
wherein the second drain region is spaced apart from the second gate stack disposed on the second sidewall of the first trench in the horizontal direction.

4. The semiconductor device of claim 2, wherein the first drain region is in contact with the first gate stack disposed on the first sidewall of the first trench, and
wherein the second drain region is in contact with the second gate stack disposed on the second sidewall of the first trench.

5. The semiconductor device of claim 1, further comprising:
a gate spacer disposed on opposite sidewalls of the first gate stack in the horizontal direction, the gate spacer comprising a first portion overlapping with the first drift region in the vertical direction and a second portion overlapping with the first trench in the vertical direction,
wherein an upper surface of the second portion of the gate spacer is formed lower than an upper surface of the first portion of the gate spacer.

6. The semiconductor device of claim 1, wherein the first gate stack comprises a gate insulating layer, a gate electrode contacting an upper surface of the gate insulating layer, and a capping pattern contacting the gate electrode, and
wherein sidewalls of the gate insulating layer, the gate electrode and the capping pattern are vertically aligned with each other.

7. The semiconductor device of claim 1, wherein a portion of the first gate stack contacts an upper surface of the first drift region, and
wherein a portion of the second gate stack is in contact with an upper surface of the second drift region.

8. The semiconductor device of claim 1, wherein the second gate stack is spaced apart from the first gate stack in the horizontal direction on the bottom surface of the first trench.

9. The semiconductor device of claim 1, further comprising:
a second trench recessed from the bottom surface of the first trench toward the lower surface of the substrate,
wherein a width of the second trench in the horizontal direction is smaller than a width of the first trench in the horizontal direction,
wherein the first gate stack is conformally disposed along a first sidewall and a bottom surface of the second trench, and
wherein the second gate stack is conformally disposed along a second sidewall and the bottom surface of the second trench.

10. The semiconductor device of claim 9, wherein the second gate stack is spaced apart from the first gate stack in the horizontal direction on the bottom surface of the second trench.

11. The semiconductor device of claim 9, wherein bottom surfaces of the first drift region and the second drift region are formed higher than the bottom surface of the second trench.

12. The semiconductor device of claim 9, wherein the portion of the first drift region overlaps with the bottom surface of the second trench in the vertical direction, and
wherein the portion of the second drift region overlaps with the bottom surface of the second trench in the vertical direction.

13. A semiconductor device comprising:
a substrate;
a well region disposed inside the substrate;
a first trench recessed from an upper surface of the substrate toward a lower surface of the substrate;
a first drift region disposed at a first side of the first trench in a horizontal direction inside the well region, a portion of the first drift region overlapping with a bottom surface of the first trench in a vertical direction;
a second drift region disposed at a second side of the first trench opposite to the first side of the first trench in the horizontal direction inside the well region, the second drift region spaced apart from the first drift region in the horizontal direction, a portion of the second drift region overlapping with the bottom surface of the first trench in the vertical direction;
a first gate stack contacting the first drift region inside the first trench;
a second gate stack contacting the second drift region inside the first trench, the second gate stack spaced apart from the first gate stack in the horizontal direction;
a first gate spacer disposed on opposite sidewalls of the first gate stack in the horizontal direction, the first gate spacer comprising a first portion overlapping the first drift region in the vertical direction and a second portion overlapping the first trench in the vertical direction; and
a second gate spacer disposed on opposite sidewalls of the second gate stack in the horizontal direction, the second gate spacer comprising a first portion overlapping with the second drift region in the vertical direction and a second portion overlapping with the first trench in the vertical direction,
wherein an upper surface of the second portion of the first gate spacer is formed lower than an upper surface of the first portion of the first gate spacer, and
wherein an upper surface of the second portion of the second gate spacer is formed lower than an upper surface of the first portion of the second gate spacer.

14. The semiconductor device of claim 13, further comprising:
a source region disposed between the first gate stack and the second gate stack inside the well region, the source region spaced apart from each of the first and second drift regions.

15. The semiconductor device of claim 13, wherein the first gate stack is conformally disposed along a first sidewall and the bottom surface of the first trench, and
wherein the second gate stack is conformally disposed along a second sidewall and the bottom surface of the first trench.

16. The semiconductor device of claim 13, further comprising:
a first drain region disposed on one side of the first gate stack inside the first drift region; and
a second drain region disposed on one side of the second gate stack inside the second drift region.

17. The semiconductor device of claim 13, wherein the upper surface of the second portion of the first gate spacer is formed lower than an upper surface of the first drift region, and
wherein the upper surface of the second portion of the second gate spacer is formed lower than an upper surface of the second drift region.

18. The semiconductor device of claim 13, wherein a portion of the first gate stack is in contact with an upper surface of the first drift region, and
wherein a portion of the second gate stack is in contact with an upper surface of the second drift region.

19. The semiconductor device of claim 13, further comprising:
a second trench recessed from the bottom surface of the first trench toward the lower surface of the substrate,
wherein a width of the second trench in the horizontal direction is smaller than a width of the first trench in the horizontal direction,
wherein the first gate stack is conformally disposed along a first sidewall and a bottom surface of the second trench, and
wherein the second gate stack is conformally disposed along a second sidewall and the bottom surface of the second trench.

20. A semiconductor device comprising:
a substrate;
a well region disposed inside the substrate;
a first trench recessed from an upper surface of the substrate toward a lower surface of the substrate;
a first drift region disposed at a first side of the first trench in a first horizontal direction inside the well region, a portion of the first drift region overlapping with a bottom surface of the first trench in a vertical direction;
a second drift region disposed at a second side of the first trench opposite to the first side of the first trench in the first horizontal direction inside the well region, the second drift region spaced apart from the first drift region in the first horizontal direction, a portion of the second drift region overlapping with the bottom surface of the first trench in the vertical direction;
a first gate stack contacting the first drift region inside the first trench, the first gate stack conformally disposed along a first sidewall and the bottom surface of the first trench, a portion of the first gate stack contacting an upper surface of the first drift region;
a second gate stack contacting the second drift region inside the first trench, the second gate stack conformally disposed along a second sidewall and the bottom surface of the first trench, a portion of the second gate stack contacting an upper surface of the second drift region, the second gate stack spaced apart from the first gate stack in the first horizontal direction on the bottom surface of the first trench;
a source region disposed between the first gate stack and the second gate stack inside the well region, the source region spaced apart from each of the first and second drift regions;
a first drain region disposed on one side of the first gate stack inside the first drift region;
a second drain region disposed on one side of the second gate stack inside the second drift region;
a first gate spacer disposed on opposite sidewalls of the first gate stack in the first horizontal direction, the first gate spacer comprising a first portion overlapping with the first drift region in the vertical direction and a second portion overlapping with the first trench in the vertical direction; and
a second gate spacer disposed on opposite sidewalls of the second gate stack in the first horizontal direction, the second gate spacer comprising a first portion overlapping with the second drift region in the vertical direction and a second portion overlapping with the first trench in the vertical direction,
wherein an upper surface of the second portion of the first gate spacer is formed lower than an upper surface of the first portion of the first gate spacer, and
wherein an upper surface of the second portion of the second gate spacer is formed lower than an upper surface of the first portion of the second gate spacer.
